(19) United States
(12) Patent Application Publication
(10) Pub. No.: US 2026/0360432 A1
(43) Pub. Date: Nov. 12, 2026

(54) NON-VOLATILE MEMORY AND METHOD FOR TRIMMING THRESHOLD VOLTAGE OF STRING SELECTION CELL THEREOF

(71) Applicant: MACRONIX International Co., Ltd., Hsinchu (TW)

(72) Inventors: You-Liang Chou, Taichung City (TW); Wen-Che Tsai, Hualien City (TW)

(73) Assignee: MACRONIX International Co., Ltd., Hsinchu (TW)

(21) Appl. No.: 19/204,795

(22) Filed: May 12, 2025

(51) Int. Cl. G11C 16/10; G11C 16/04; G11C 16/34

(52) U.S. Cl. CPC G11C 16/102; G11C 16/0483; G11C 16/3404

(57) ABSTRACT

Provided are a non-volatile memory, which may be a three-dimensional NAND flash memory with high capacity and high performance, and a method for trimming threshold voltage of a string selection cell thereof. A control circuit trims threshold voltages of a plurality of string selection cells of a memory cell string, so that the threshold voltages of the string selection cells are different from each other. When a threshold voltage of a first string selection cell is trimmed, a first programming voltage is provided to a gate of the first string selection cell to program the first string selection cell. When a threshold voltage of a second string selection cell is trimmed, a second programming voltage different from the first programming voltage is provided to a gate of the second string selection cell to program the second string selection cell.

### BACKGROUND

### Technical Field

The disclosure relates to a memory circuit, and particularly relates to a non-volatile memory and a method for trimming threshold voltage of a string selection cell thereof.

### Related Art

Integrated circuits containing high-capacity and high-performance three-dimensional NAND flash memory (3D NAND flash memory) are continuously under development. To overcome the problems of size reduction, the NAND flash memory industry has transitioned from planar architecture to 3D architecture. The storage capacity of 3D vertical NAND flash memory has been continuously increasing over the past decade to meet the demands of various industries, including mobile and data centers. The increase in the number of stacked word-line (WL) layers has played a key role in achieving higher storage capacity or bit density. This paradigm shift allows for increased storage density through vertical stacking of storage units, rather than relying solely on cell miniaturization. Charge-trap technology employs a continuous silicon nitride layer as a storage node (SN). Compared to floating gate technology, the charge-trap technology is widely used in 3D NAND flash memory arrays due to the simpler process and higher vertical scaling capability thereof.

With technological advancements, the fabrication of 3D NAND flash memory arrays has progressed from CnA (CMOS Near Array) technology and CuA (CMOS Under Array) technology to CbA (CMOS directly Bonded to Array) technology. The wire connection method of the CbA memory cell string array differs from the wire connection methods of CnA and CuA. How to trim threshold voltages of string selection cells of CbA memory cell string arrays is one of many technical issues in the flash memory field.

### SUMMARY

The disclosure provides a non-volatile memory and a method for trimming threshold voltage of a string selection cell thereof, so that threshold voltages of multiple string selection cells of the same memory cell string are different from each other.

In an embodiment of the disclosure, the non-volatile memory includes a memory cell string array and a control circuit. The memory cell string array includes multiple memory cell strings. Each of multiple word lines is coupled to a corresponding memory cell in each of the memory cell strings. Each of multiple bit lines is coupled to an upper end of each of the memory cell strings in a corresponding column of the memory cell string array. Each of multiple common source lines is coupled to a lower end of each of the memory cell strings in a corresponding row of the memory cell string array. A current memory cell string among the memory cell strings includes multiple string selection cells, multiple memory cells, and a ground selection switch. The string selection cells of the current memory cell string are connected in series between the memory cells of the current memory cell string and the upper end of the current memory cell string. The ground selection switch of the current memory cell string is connected in series between the memory cells of the current memory cell string and the lower end of the current memory cell string. The control circuit is coupled to the memory cell string array. The control circuit trims threshold voltages of the string selection cells of the current memory cell string, so that the threshold voltages of the string selection cells of the current memory cell string are different from each other. During a first programming period that a threshold voltage of a first string selection cell among the string selection cells of the current memory cell string is trimmed, the control circuit turns on the memory cells and the ground selection switch of the current memory cell string, the control circuit provides a non-inhibition voltage to a current common source line among the common source lines that is connected to the current memory cell string, the control circuit provides a inhibition voltage to other common source lines among the common source lines except the current common source line, and the control circuit provides a first programming voltage to a gate of the first string selection cell to program the first string selection cell. During a second programming period that a threshold voltage of a second string selection cell among the string selection cells of the current memory cell string is trimmed, the control circuit turns on the memory cells and the ground selection switch of the current memory cell string, the control circuit provides the non-inhibition voltage to the current common source line among the common source lines that is connected to the current memory cell string, the control circuit provides the inhibition voltage to other common source lines among the common source lines except the current common source line, and the control circuit provides a second programming voltage different from the first programming voltage to a gate of the second string selection cell to program the second string selection cell.

In an embodiment of the disclosure, the method for trimming threshold voltage includes the following. Threshold voltages of multiple string selection cells of a current memory cell string of a memory cell string array are trimmed, so that the threshold voltages of the string selection cells of the current memory cell string are different from each other, in which the current memory cell string further includes multiple memory cells and a ground selection switch. Also, during a first programming period that a threshold voltage of a first string selection cell among the string selection cells of the current memory cell string is trimmed, the memory cells and the ground selection switch of the current memory cell string are turned on, a non-inhibition voltage is provided to a current common source line that is connected to the current memory cell string, a inhibition voltage is provided to other common source lines except the current common source line, and a first programming voltage is provided to a gate of the first string selection cell to program the first string selection cell. Also, during a second programming period that a threshold voltage of a second string selection cell among the string selection cells of the current memory cell string is trimmed, the memory cells and the ground selection switch of the current memory cell string are turned on, a non-inhibition voltage is provided to a current common source line that is connected to the current memory cell string, a inhibition voltage is provided to other common source lines except the current common source line, and a second programming voltage different from the first programming voltage is provided to a gate of the second string selection cell to program the second string selection cell.

Based on the above, during the period that threshold voltages of multiple string selection cells of a target string (referred to as the current memory cell string) among multiple memory cell strings are trimmed, the control circuit turns on all memory cells and the ground selection switch of the current memory cell string, provides a non-inhibition voltage to the common source line (referred to as the current common source line) that is connected to the current memory cell string, and provides a inhibition voltage to other common source lines except the current common source line. When the threshold voltage of the first string selection cell of the current memory cell string is trimmed, the first programming voltage is provided to the gate of the first string selection cell to program the threshold voltage of the first string selection cell to a first threshold voltage. When the threshold voltage of the second string selection cell of the current memory cell string is trimmed, the second programming voltage (different from the first programming voltage) is provided to the gate of the second string selection cell to program the threshold voltage of the second string selection cell to a second threshold voltage (different from the first threshold voltage). Therefore, the non-volatile memory and the method for trimming threshold voltage of the string selection cell thereof may trim the threshold voltages of the string selection cells of the memory cell string array, so that the threshold voltages of multiple string selection cells of the same memory cell string are different from each other.

To make the foregoing characteristics and advantages of the disclosure more comprehensible, embodiments are provided below with detailed descriptions together with the accompanying drawings.

### BRIEF DESCRIPTION OF THE DRAWINGS

FIG. 1 is a circuit block diagram of a non-volatile memory according to an embodiment of the disclosure.

FIG. 2 is a circuit diagram of a current memory cell string according to an embodiment of the disclosure.

FIG. 3 is a flow diagram of a method for trimming threshold voltage of a string selection cell according to an embodiment of the disclosure.

FIG. 4 is a waveform diagram illustrating threshold voltage trimming of the string selection cell according to an embodiment of the disclosure.

FIG. 5 is a schematic diagram showing a relationship curve of a programming voltage versus a threshold voltage according to an embodiment of the disclosure.

### DESCRIPTION OF THE EMBODIMENTS

The term “couple (or connect)” used throughout this specification (including the claims) may refer to any direct or indirect connection means. For example, if a first device is described as being coupled (or connected) to a second device, it should be interpreted that the first device may be directly connected to the second device, or the first device may be indirectly connected to the second device through other devices or some connection means. The terms such as “first” and “second” mentioned throughout this specification (including the claims) are used to name elements or to distinguish different embodiments or ranges, and are not intended to limit the maximum or minimum number of elements, nor to limit the order of elements. Additionally, where possible, elements/components/steps with the same reference numerals in the drawings and embodiments represent the same or similar parts. The elements/components/steps with the same reference numerals or using the same terms in different embodiments may be referred to each other for related descriptions.

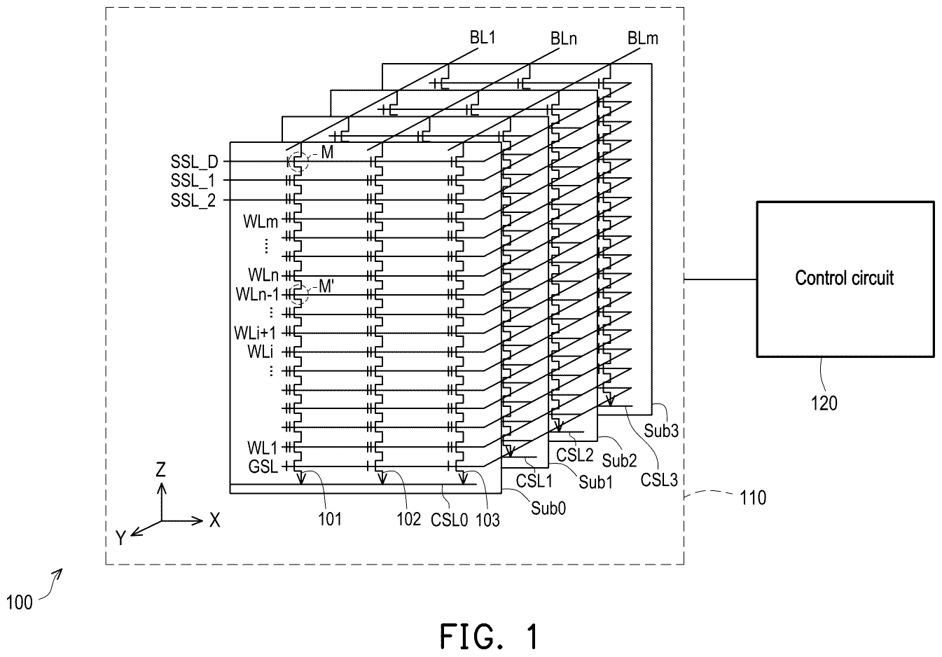

FIG. 1 is a circuit block diagram of a non-volatile memory 100 according to an embodiment of the disclosure. The non-volatile memory 100 includes a memory cell string array 110 and a control circuit 120. FIG. 1 shows an equivalent circuit of a three dimensional (3D) NAND flash memory integrated circuit in a three-dimensional manner. The memory cell string array 110 includes multiple memory cell strings (such as memory cell strings 101, 102, or 103), and each memory cell string includes multiple memory cells (such as a memory cell M′) connected in series along a Z direction. The multiple memory cells in the memory cell string array 110 shown in FIG. 1 are arranged in a 3D manner in an XYZ coordinate system. However, the arrangement does not mean that the circuit of the memory cell string array 110 is limited to a 3D manner. In one example, the memory cell string array 110 may be divided into four sub-blocks Sub0, Sub1, Sub2, and Sub3. In this example, multiple memory cell strings (such as the memory cell strings 101, 102, and 103) on the same plane (defined by the X direction and the Z direction) may be defined as one sub-block (such as the sub-block Sub0).

The memory cell string array 110 includes multiple word lines (WL), such as word lines WL1, . . . , WLi, WLi+1, . . . , WLn−1, WLn, . . . , WLm shown in FIG. 1. The number of word lines of the memory cell string array 110 may be determined according to actual design and application. A word line (such as word line WLn) may correspond to one layer (a plane defined by the X direction and the Y direction) of the memory cell array. Each of the word lines WL1 to WLm is coupled to a corresponding memory cell in each memory cell string. A string selection line (SSL) SSL_D is coupled to a control end of an end switch cell of each memory cell string. For example, a control end of an end switch cell M of the memory cell string 101 is coupled to the string selection line SSL_D. A ground select line GSL is coupled to a control end of a ground select transistor of each memory cell string. The end switch cell and the ground select transistor are at opposite sides in each memory cell string (such as the memory cell string 101).

The memory cell string array 110 further includes multiple bit lines (BL), such as bit lines BL1, BLn, and BLm shown in FIG. 1. The number of bit lines of the memory cell string array 110 may be determined according to actual design and application. Each bit line is coupled to an upper end of each memory cell string in a corresponding column of the memory cell string array 110. For example, an upper end of the end switch cell M of the memory cell string 101 is coupled to the bit line BL1. The memory cell string array 110 further includes multiple common source lines (CSL), such as common source lines CSL0, CSL1, CSL2, and CSL3 shown in FIG. 1. The number of common source lines of the memory cell string array 110 may be determined according to actual design and application. Each common source line is coupled to a lower end of each memory cell string in a corresponding row of the memory cell string array 110. For example, the common source line CSL0 is coupled to lower ends of the memory cell strings 101, 102, and 103 in the sub-block Sub0.

The memory cell string array 110 further includes multiple string selection lines, such as string selection lines SSL_1 and SSL_2 shown in FIG. 1. The number of string selection lines of the memory cell string array 110 may be determined according to actual design and application. For example, in other embodiments, the memory cell string array 110 includes three string selection lines SSL_1, SSL_2, and SSL_3 (not shown) or more string selection lines. Each of the string selection lines SSL_1 and SSL_2 is coupled to the control end of the string selection cell of each memory cell string. The string selection cells in the same memory cell string have various threshold voltages. The threshold voltage arrangement of the string selection cells of the same memory cell string is referred to as a threshold voltage configuration mode. The string selection cells of different sub-blocks Sub0, Sub1, Sub2, and Sub3 have different threshold voltage configuration modes. Therefore, through the configuration of the string selection lines SSL_1 and SSL_2, and through the configuration of the threshold voltage configuration mode, the memory cell string may be selected.

In one example, one or more dummy lines or layers (not shown) may be disposed between the string selection line (for example, the string selection line SSL_2) and the uppermost word line layer (for example, the word line WLm), and between the ground select line GSL and the lowermost word line layer (for example, the word line WL1). In another example, one or more dummy lines or layers (not shown) may be disposed in a middle portion of each memory cell string (such as the memory cell strings 101, 102, or 103).

The non-volatile memory 100 further includes the control circuit 120, used to implement corresponding operations on the memory cell string array 110. The control circuit 120 is coupled to the memory cell string array 110. According to different designs, in some embodiments, the control circuit 120 may be implemented as hardware circuits. In other embodiments, the control circuit 120 may be implemented as a combination of multiple ones of hardware, firmware, and software (that is, programs).

In terms of hardware form, the control circuit 120 may be implemented as a logic circuit on an integrated circuit. For example, the related functions of the control circuit 120 may be implemented in various logic blocks, modules, and circuits in one or more hardware controllers, microcontrollers, hardware processors, microprocessors, application-specific integrated circuits (ASIC), digital signal processors (DSP), field programmable gate arrays (FPGA), central processing units (CPU), and/or other processing units. The related functions of the control circuit 120 may be implemented as hardware circuits, such as various logic blocks, modules, and circuits in integrated circuits, using hardware description languages (for example, Verilog HDL or VHDL) or other suitable programming languages.

In terms of software form and/or firmware form, the related functions of the control circuit 120 may be implemented as programming codes. For example, the control circuit 120 may be implemented using general programming languages (such as C, C++, or assembly language) or other suitable programming languages. The programming codes may be recorded/stored in a “non-transitory machine-readable storage medium”. In some embodiments, the non-transitory machine-readable storage medium may include, for example, semiconductor memory and/or storage devices. Electronic devices (such as CPU, hardware controllers, microcontrollers, hardware processors, or microprocessors) may read and execute the programming codes from the non-transitory machine-readable storage medium, thereby implementing the related functions of the control circuit 120.

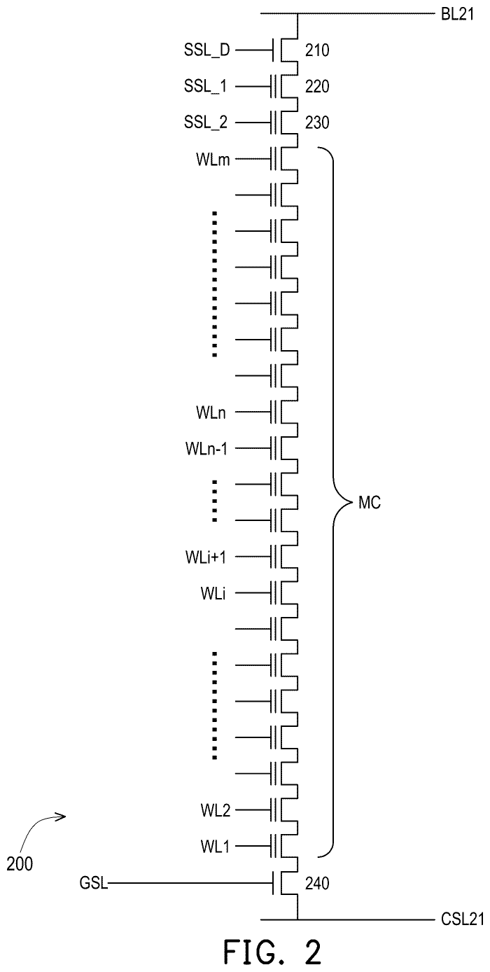

FIG. 2 is a circuit schematic diagram of a current memory cell string 200 according to an embodiment of the disclosure. The current memory cell string 200 shown in FIG. 2 may serve as one of many implementation examples for each memory cell string (such as the memory cell strings 101, 102, or 103) shown in FIG. 1. For a current bit line BL21 shown in FIG. 2, reference may be made to the related descriptions of the bit lines BL1, BLn, or BLm shown in FIG. 1, for the string selection lines SSL_D, SSL_1, and SSL_2 shown in FIG. 2, reference may be made to the related descriptions in FIG. 1, for the word lines WLm, WLn, WLn−1, WLi+1, WLi, WL2, and WL1 shown in FIG. 2, reference may be made to the related descriptions in FIG. 1, for the ground select line GSL shown in FIG. 2, reference may be made to the related descriptions in FIG. 1, and for a common source line CSL21 shown in FIG. 2, reference may be made to the related descriptions of the common source lines CSL0, CSL1, CSL2, or CSL3 shown in FIG. 1, so details will not be repeated here.

In the embodiment shown in FIG. 2, the current memory cell string 200 includes an end switch cell 210, a string selection cell 220, a string selection cell 230, multiple memory cells MC, and a ground selection switch 240. For the end switch cell 210 shown in FIG. 2, reference may be made to the related descriptions of the end switch cell (such as the end switch cell M) shown in FIG. 1. The end switch cell 210 is connected in series between the string selection cell 220 of the current memory cell string 200 and the upper end the (current bit line BL21) of the current memory cell string 200. During a programming period that a threshold voltage of the string selection cell 220 of the current memory cell string 200 is trimmed, and during a programming period that a threshold voltage of the string selection cell 230 of the current memory cell string 200 is trimmed, the control circuit 120 turns off the end switch cell 210. Based on actual design and application, the end switch cell 210 may include a single transistor, or may include multiple transistors connected in series. The number of transistors in the end switch cell 210 may be determined based on actual design.

For the multiple memory cells MC shown in FIG. 2, reference may be made to the related descriptions of the memory cells (such as the memory cell M′) shown in FIG. 1. The number of the memory cells MC may be determined based on actual design. The string selection cells 220 and 230 of the current memory cell string 200 are connected in series between the memory cells MC of the current memory cell string 200 and the upper end of the current memory cell string 200. The ground selection switch 240 of the current memory cell string 200 is connected in series between the memory cells MC of the current memory cell string 200 and the lower end of the current memory cell string 200.

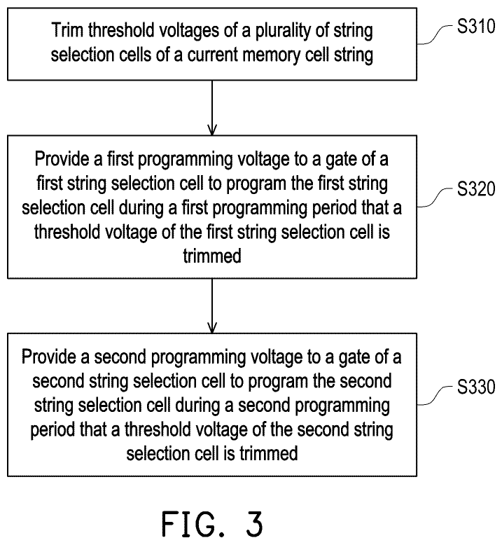

FIG. 3 is a flow diagram of a method for trimming threshold voltage of a string selection cell according to an embodiment of the disclosure. Referring to FIG. 2 and FIG. 3, in Step S310, the control circuit 120 trims threshold voltages of the string selection cells 220 and 230 of the current memory cell string 200, so that the threshold voltages of the string selection cells 220 and 230 of the current memory cell string 200 are different from each other. During a period that the threshold voltages of the string selection cells 220 and 230 of the current memory cell string 200 are trimmed, the control circuit 120 turns on the memory cells MC and the ground selection switch 240 of the current memory cell string 200, the control circuit 120 provides a non-inhibition voltage to the current common source line CSL21 among the common source lines that is connected to the current memory cell string 200, and the control circuit 120 provides a inhibition voltage to other common source lines among the common source lines except the current common source line CSL21.

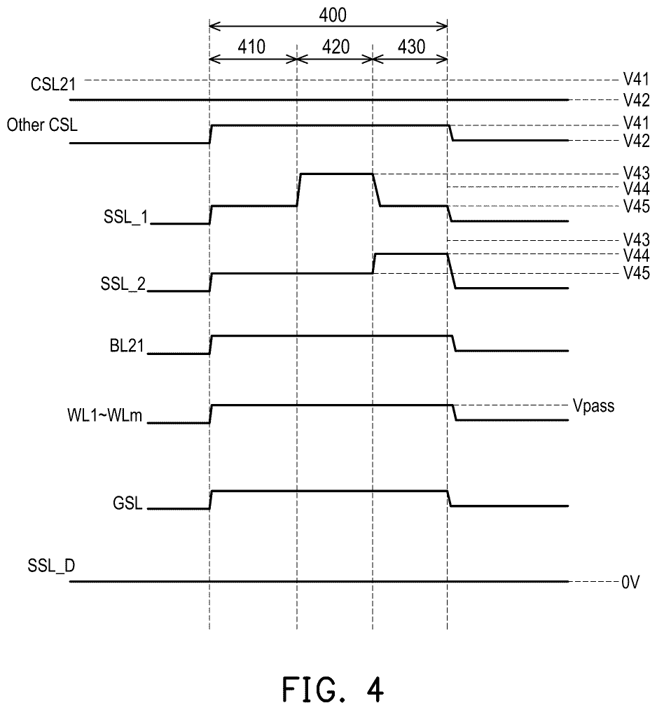

FIG. 4 is a waveform diagram illustrating threshold voltage trimming of the string selection cells 220 and 230 according to an embodiment of the disclosure. Referring to FIG. 2, FIG. 3, and FIG. 4, during a period 400 that the threshold voltages of the string selection cells 220 and 230 of the current memory cell string 200 are trimmed, the control circuit 120 provides a control voltage (such as 0V or other voltage level) to the string selection line SSL_D to turn off the end switch cell 210. The control circuit 120 provides a control voltage (such as 5V or other voltage level) to the ground select line GSL during the period 400 to turn on the ground selection switch 240. The control circuit 120 provides a control voltage Vpass (such as 7V or other voltage level) to the word lines WL1 to WLm during the period 400 that the threshold voltages are trimmed to turn on all memory cells MC of the current memory cell string 200. During the period 400 that the threshold voltages are trimmed, the control circuit 120 further raises the voltage of the current bit line BL21 (for example, raising to 3V or other voltage level) to ensure that the end switch cell 210 is turned off.

In addition, during the period 400, the control circuit 120 provides a non-inhibition voltage V42 (such as 0V or other voltage level) to the current common source line CSL21 among multiple common source lines that is connected to the current memory cell string 200, and the control circuit 120 provides a inhibition voltage V41 (such as a voltage level greater than or equal to 5V) to other common source lines except the current common source line CSL21. The levels of the inhibition voltage V41 and the non-inhibition voltage V42 may be determined according to actual design and application.

The period 400 that the threshold voltages are trimmed includes a pre-conduction period 410, a programming period 420, and a programming period 430. During the pre-conduction period 410, the control circuit 120 provides a pre-conduction voltage V45 (such as 7V or other voltage level) to the string selection lines SSL_1 and SSL_2 to turn on the string selection cells 220 and 230 of the current memory cell string 200. The level of the pre-conduction voltage V45 may be determined according to actual design and application.

During the programming period 420 that the threshold voltage of the string selection cell 220 of the current memory cell string 200 is trimmed, the control circuit 120 provides a programming voltage V43 (such as 20V or other voltage level) to the gate of the string selection cell 220 through the string selection line SSL_1 (Step S320), so that the threshold voltage of the string selection cell 220 is programmed to a first threshold voltage. The level of the programming voltage V43 may be determined according to actual design and application. Based on actual design and application, the string selection cell 220 may include a single transistor, or may include multiple transistors connected in series. The number of transistors in the string selection cell 220 may be determined based on actual design. During the programming period 420, the control circuit 120 provides the pre-conduction voltage V45 to the string selection line SSL_2.

Based on actual design and application, the string selection cell 230 may include a single transistor, or may include multiple transistors connected in series. The number of transistors in the string selection cell 230 may be determined based on actual design. During the programming period 430 that the threshold voltage of the string selection cell 230 of the current memory cell string 200 is trimmed, the control circuit 120 provides a programming voltage V44 (different from the programming voltage V43 of the selection cell 220, such as 16V or other voltage level) to the gate of the string selection cell 230 through the string selection line SSL_2 (Step S330), so that the threshold voltage of the string selection cell 230 is programmed to a second threshold voltage (different from the first threshold voltage of the selection cell 220). The level of the programming voltage V44 may be determined according to actual design and application. During the programming period 430, the control circuit 120 provides the pre-conduction voltage V45 to the string selection line SSL_1.

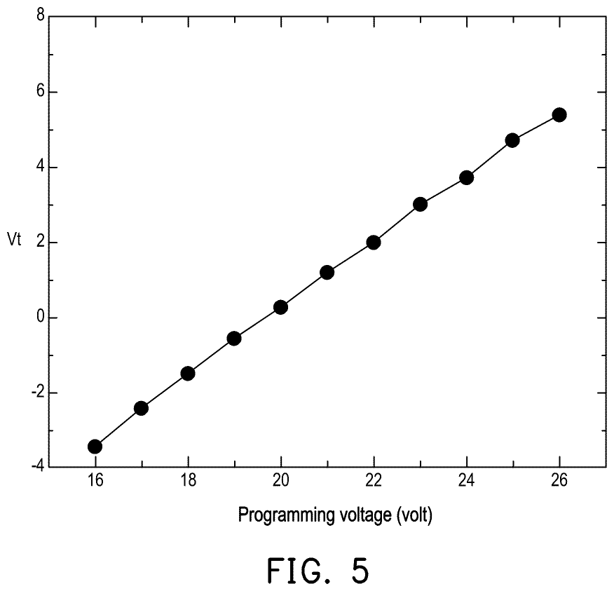

The levels of the programming voltages V43 and V44 may be determined according to actual design and application. For example, the programming voltages V43 and V44 are two voltages in a range of 16 volts to 26 volts. Generally, the higher the programming voltage, the higher the threshold voltage. FIG. 5 is a schematic diagram showing a relationship curve of the programming voltage versus a threshold voltage Vt according to an embodiment of the disclosure. The horizontal axis of FIG. 5 represents the programming voltage, while the vertical axis represents the threshold voltage Vt of the string selection cell. From the relationship curve of FIG. 5, it may be seen that the higher the programming voltage applied to the gate of the string selection cell, the higher the threshold voltage Vt of the string selection cell. By appropriately selecting the programming voltage applied to the gate of the string selection cell, the control circuit 120 may trim the threshold voltage of the string selection cell 220 and the threshold voltage of 230, so that the threshold voltages of the string selection cells 220 and 230 are different from each other.

In summary, during the period 400 that the threshold voltages of multiple string selection cells (for example, the string selection cells 220 and 230 of the current memory cell string 200) in a target string among multiple memory cell strings are trimmed, the control circuit 120 turns on all memory cells MC and the ground selection switch 240 of the current memory cell string 200, provides the non-inhibition voltage V42 to the common source line (referred to as the current common source line) CSL21 that is connected to the current memory cell string 100, and provides the inhibition voltage V41 to other common source lines except the current common source line CSL21. When (in the programming period 420) the threshold voltage of the string selection cell 220 of the current memory cell string 200 is trimmed, the programming voltage (for example, the programming voltage V43) is provided to the gate of the string selection cell 220 to program the threshold voltage of the string selection cell 220 to the first threshold voltage. When the threshold voltage of the string selection cell 230 of the current memory cell string 200 is trimmed, the programming voltage (for example, the programming voltage V44) is provided to the gate of the string selection cell 230 to program the threshold voltage of the string selection cell 230 to the second threshold voltage (different from the first threshold voltage). Therefore, the non-volatile memory 100 and the method for trimming threshold voltage of the string selection cell thereof may trim the threshold voltages of the string selection cells of the memory cell string array 110, so that the threshold voltages of multiple string selection cells of the same memory cell string are different from each other.

Although the disclosure has been disclosed in the foregoing embodiments, the embodiments are not intended to limit the disclosure. Persons with ordinary knowledge in the relevant technical field may make some changes and modifications without departing from the spirit and scope of the disclosure. Therefore, the protection scope of the disclosure shall be defined by the appended claims.

What is claimed is:

1. A non-volatile memory comprising:
a memory cell string array comprising a plurality of memory cell strings, wherein each of a plurality of word lines is coupled to a corresponding memory cell in each of the memory cell strings, each of a plurality of bit lines is coupled to an upper end of each of the memory cell strings in a corresponding column of the memory cell string array, each of a plurality of common source lines is coupled to a lower end of each of the memory cell strings in a corresponding row of the memory cell string array, a current memory cell string among the memory cell strings comprises a plurality of string selection cells, a plurality of memory cells, and a ground selection switch, the string selection cells of the current memory cell string are connected in series between the memory cells of the current memory cell string and the upper end of the current memory cell string, and the ground selection switch of the current memory cell string is connected in series between the memory cells of the current memory cell string and the lower end of the current memory cell string; and
a control circuit coupled to the memory cell string array, wherein
the control circuit trims threshold voltages of the string selection cells of the current memory cell string, so that the threshold voltages of the string selection cells of the current memory cell string are different from each other; and
during a first programming period that a threshold voltage of a first string selection cell among the string selection cells of the current memory cell string is trimmed, the control circuit turns on the memory cells and the ground selection switch of the current memory cell string, the control circuit provides a non-inhibition voltage to a current common source line among the common source lines that is connected to the current memory cell string, the control circuit provides a inhibition voltage to other common source lines among the common source lines except the current common source line, and the control circuit provides a first programming voltage to a gate of the first string selection cell to program the first string selection cell; and
during a second programming period that a threshold voltage of a second string selection cell among the string selection cells of the current memory cell string is trimmed, the control circuit turns on the memory cells and the ground selection switch of the current memory cell string, the control circuit provides the non-inhibition voltage to the current common source line among the common source lines that is connected to the current memory cell string, the control circuit provides the inhibition voltage to other common source lines among the common source lines except the current common source line, and the control circuit provides a second programming voltage different from the first programming voltage to a gate of the second string selection cell to program the second string selection cell.

2. The non-volatile memory as claimed in claim 1, wherein during a pre-conduction period before the first programming period, the control circuit turns on the first string selection cell, the second string selection cell, the memory cells, and the ground selection switch of the current memory cell string, the control circuit provides the non-inhibition voltage to the current common source line, and the control circuit provides the inhibition voltage to other common source lines among the common source lines except the current common source line.

3. The non-volatile memory as claimed in claim 1, wherein the current memory cell string further comprises an end switch cell, the end switch cell is connected in series between the string selection cells of the current memory cell string and the upper end of the current memory cell string, and during the first programming period that the threshold voltage of the first string selection cell of the current memory cell string is trimmed, the control circuit turns off the end switch cell.

4. The non-volatile memory as claimed in claim 3, wherein during the first programming period that the threshold voltage of the first string selection cell of the current memory cell string is trimmed, the control circuit raises a voltage of a current bit line connected to the current memory cell string to turn off the end switch cell.

5. The non-volatile memory as claimed in claim 1, wherein the inhibition voltage is greater than or equal to 5 volts, the non-inhibition voltage is 0 volt, and the first programming voltage and the second programming voltage are two voltages in a range of 16 to 26 volts.

6. A method for trimming threshold voltage of a string selection cell, comprising:
trimming threshold voltages of a plurality of string selection cells of a current memory cell string of a memory cell string array, so that the threshold voltages of the string selection cells of the current memory cell string are different from each other, wherein each of a plurality of word lines is coupled to a corresponding memory cell in each of a plurality of memory cell strings of the memory cell string array, each of a plurality of bit lines is coupled to an upper end of each of the memory cell strings in a corresponding column of the memory cell string array, each of a plurality of common source lines is coupled to a lower end of each of the memory cell strings in a corresponding row of the memory cell string array, the current memory cell string further comprises a plurality of memory cells and a ground selection switch, the string selection cells of the current memory cell string are connected in series between the memory cells of the current memory cell string and the upper end of the current memory cell string, and the ground selection switch of the current memory cell string is connected in series between the memory cells of the current memory cell string and the lower end of the current memory cell string; and
during a first programming period that a threshold voltage of a first string selection cell among the string selection cells of the current memory cell string is trimmed, turning on the memory cells and the ground selection switch of the current memory cell string, providing a non-inhibition voltage to a current common source line among the common source lines that is connected to the current memory cell string, providing a inhibition voltage to other common source lines among the common source lines except the current common source line, and providing a first programming voltage to a gate of the first string selection cell to program the first string selection cell; and
during a second programming period that a threshold voltage of a second string selection cell among the string selection cells of the current memory cell string is trimmed, turning on the memory cells and the ground selection switch of the current memory cell string, providing the non-inhibition voltage to the current common source line among the common source lines that is connected to the current memory cell string, providing the inhibition voltage to other common source lines among the common source lines except the current common source line, and providing a second programming voltage different from the first programming voltage to a gate of the second string selection cell to program the second string selection cell.

7. The method for trimming threshold voltage as claimed in claim 6, further comprising:
during a pre-conduction period before the first programming period, turning on the first string selection cell, the second string selection cell, the memory cells, and the ground selection switch of the current memory cell string, providing the non-inhibition voltage to the current common source line, and providing the inhibition voltage to other common source lines among the common source lines except the current common source line.

8. The method for trimming threshold voltage as claimed in claim 6, wherein the current memory cell string further comprises an end switch cell, the end switch cell is connected in series between the string selection cells of the current memory cell string and the upper end of the current memory cell string, and the method for trimming threshold voltage further comprises:
turning off the end switch cell during the first programming period that the threshold voltage of the first string selection cell of the current memory cell string is trimmed.

9. The method for trimming threshold voltage as claimed in claim 8, further comprising:
raising a voltage of a current bit line connected to the current memory cell string to turn off the end switch cell during the first programming period that the threshold voltage of the first string selection cell of the current memory cell string is trimmed.

10. The method for trimming threshold voltage as claimed in claim 6, wherein the inhibition voltage is greater than or equal to 5 volts, the non-inhibition voltage is 0 volt, and the first programming voltage and the second programming voltage are two voltages in a range of 16 to 26 volts.
